(19) United States
(12) Patent Application Publication
(10) Pub. No.: US 2026/0353622 A1
(43) Pub. Date: Nov. 5, 2026

(54) MOUNTING DEVICE AND PROCESSING REGION SETTING METHOD

(71) Applicant: FUJI CORPORATION, Chiryu (JP)

(72) Inventors: Takahiro KOBAYASHI, Chiryu-shi (JP); Keiichi ONO, Anjo-shi (JP); Nobuya SUGIURA, Toyokawa-shi (JP)

(73) Assignee: FUJI CORPORATION, Chiryu (JP)

(21) Appl. No.: 19/486,300

(22) PCT Filed: Jun. 13, 2023
(86) PCT No.: PCT/JP2023/021899

§ 371 Date: Nov. 20, 2025

(51) Int. Cl. H05K 13/00; H05K 13/04; H05K 13/08

(52) U.S. Cl. CPC H05K 13/0015; H05K 13/0406; H05K 13/0812

(57) ABSTRACT

A mounting device configured to pick up a component supplied to a supply position by a pickup member, perform image processing on an image captured after the pickup to recognize a pickup deviation of the component, and correct the pickup deviation to mount the component, the mounting device including: an acquisition section configured to, when simultaneous pickup of multiple components is performed by multiple pickup members, acquire a positional deviation of each pickup member with respect to each supply position of each target component for the simultaneous pickup for each of the pickup members; and a setting section configured to set a processing region of the image processing for each target component by offsetting a predetermined region defined in the image for each of the pickup members that have simultaneously picked up the target components, based on the positional deviation of each pickup member acquired by the acquisition section.

### TECHNICAL FIELD

The present description discloses a mounting device and a processing region setting method.

### BACKGROUND ART

Conventionally, in a mounting device capable of simultaneously picking up multiple components using multiple pickup members, a device is proposed that performs image processing on a captured image of the simultaneously picked-up components to recognize a pickup deviation of the components, and corrects the pickup deviation to mount each component. For example, in a mounting device of Patent Literature 1, a region obtained by adding a constant in consideration of inclination, pickup deviation, and the like of a component to a component size is set for each component, and image processing is performed on the set region as a processing region, thereby recognizing the pickup deviation for each component.

### CITATION LIST

### Patent Literature

Patent Literature 1: JP-A-2004-055702

### BRIEF SUMMARY

### Technical Problem

Here, a pickup position itself of the pickup member that performs the simultaneous pickup may deviate from a supply position where the component is supplied. Therefore, it is conceivable to set a processing region larger than that in Patent Literature 1 in consideration of the deviation of the pickup position itself, but it takes more time than necessary for image processing.

A main object of the present disclosure is to prevent a processing region of image processing from being larger than necessary when simultaneous pickup is performed.

### Solution to Problem

The present disclosure adopts the following means to achieve the above-described main object.

A mounting device of the present disclosure is
a mounting device configured to pick up a component supplied to a supply position by a pickup member, perform image processing on an image captured after the pickup to recognize a pickup deviation of the component, and correct the pickup deviation to mount the component, the mounting device including:
an acquisition section configured to, when simultaneous pickup of multiple components is performed by multiple pickup members, acquire a positional deviation of each pickup member with respect to each supply position of each target component for the simultaneous pickup for each of the pickup members; and
a setting section configured to set a processing region of the image processing for each target component by offsetting a predetermined region defined in the image for each of the pickup members that have simultaneously picked up the target components, based on the positional deviation of each pickup member acquired by the acquisition section.

In the mounting device of the present disclosure, the positional deviation of each pickup member with respect to each supply position of the target components for the simultaneous pickup is acquired for each pickup member. In addition, the processing region is set for each target component by offsetting the predetermined region defined in the image for each pickup member based on the positional deviation of each pickup member. As a result, it is possible to prevent the processing region of the image processing from being larger than necessary when the simultaneous pickup is performed.

### BRIEF DESCRIPTION OF DRAWINGS

FIG. 1 is a schematic configuration diagram of mounting device 10.

FIG. 2 is a schematic configuration diagram of head 40.

FIG. 3 is a block diagram illustrating an electrical connection relationship of mounting device 10.

FIG. 4 is a flowchart illustrating an example of feeder position recognition processing.

FIG. 5 is a flowchart illustrating an example of simultaneous pickup processing.

FIG. 6 is a diagram illustrating an example of center FC between target feeders and center NC between target nozzles.

FIG. 7 is a diagram illustrating an example of center FC between target feeders and center NC between target nozzles.

FIG. 8 is a diagram illustrating an example of positional deviation during simultaneous pickup.

FIG. 9 is a flowchart illustrating an example of processing region setting processing.

FIG. 10 is a diagram illustrating an example of reference processing region A0.

FIG. 11 is a diagram illustrating an example of processing region A1.

FIG. 12 is a diagram illustrating an example of processing region A2 of a comparative example.

### DESCRIPTION OF EMBODIMENTS

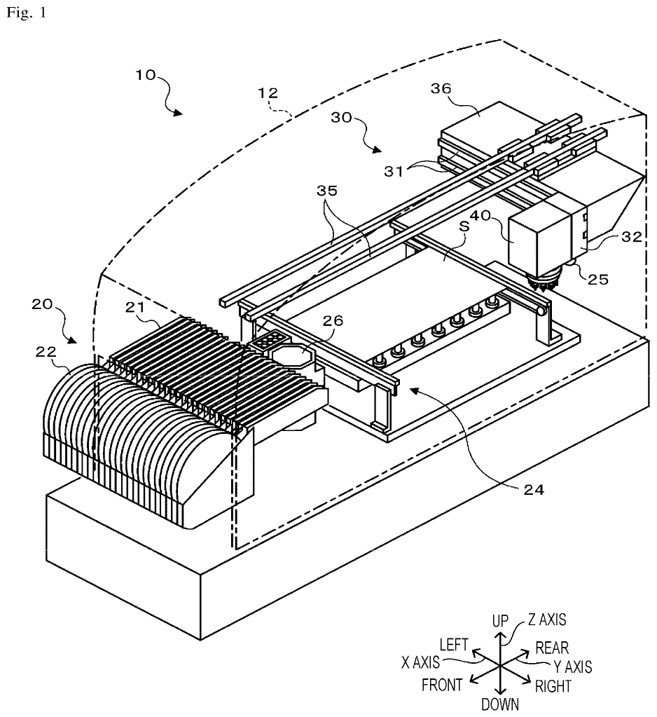

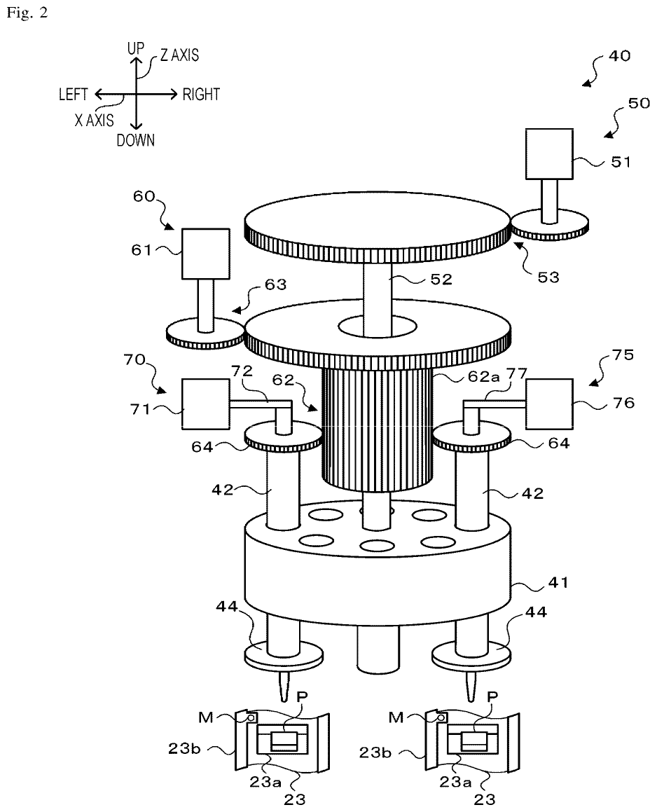

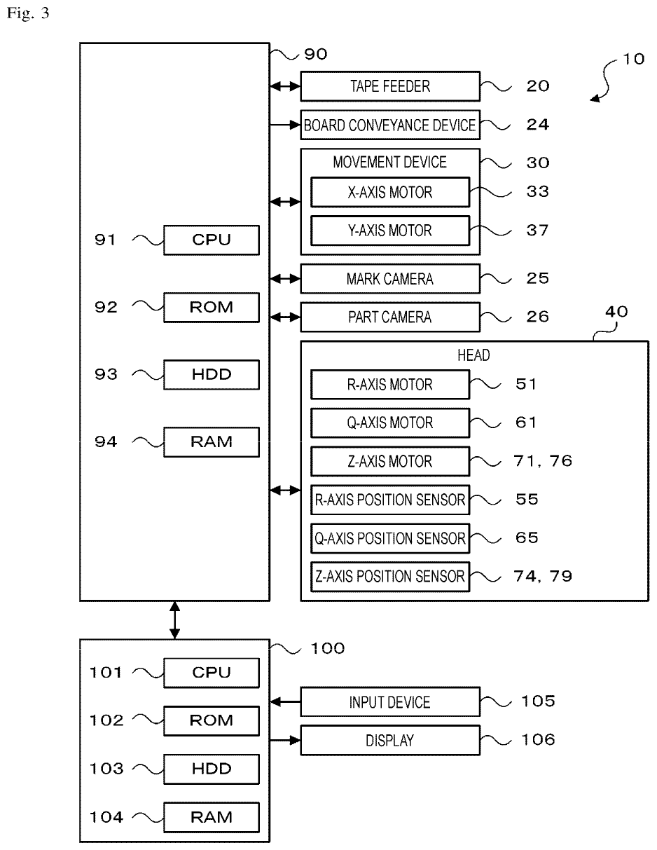

An embodiment of the present disclosure will be described with reference to the drawings. FIG. 1 is a schematic configuration diagram of mounting device 10. FIG. 2 is a schematic configuration diagram of head 40. FIG. 3 is a block diagram illustrating an electrical connection relationship of mounting device 10. In the present embodiment, it is assumed that a left-right direction (X-axis), a front-rear direction (Y-axis), and an up-down direction (Z-axis) are as illustrated in FIG. 1.

As illustrated in FIG. 1, mounting device 10 includes tape feeder 20, board convey ance device 24, movement device 30, head 40, mark camera 25, part camera 26, and control device 90 (refer to FIG. 3). Multiple mounting devices 10 are disposed in a board conveyance direction (X-axis direction) to form a mounting line. The mounting line is managed by management device 100 (refer to FIG. 3).

Multiple tape feeders 20 supply components to mounting device 10, are detachably set in each slot formed in a feeder table on the front side of mounting device 10, and are attached side by side in the X-axis direction (left-right direction). Tape feeder 20 includes feeder section 21 and reel 22 on which tape 23 is wound, and pulls out tape 23 from reel 22 by a feeding mechanism (not illustrated) of feeder section 21 to feed tape 23 to a supply position of the component. Cavities 23a (refer to FIG. 2) are formed in tape 23 at predetermined intervals along the longitudinal direction thereof. Component P is accommodated in cavity 23a. Component P accommodated in cavity 23a is protected by a film covering the surface of tape 23, is exposed at the supply position by peeling the film before the supply position, and can be picked up by suction nozzle 44 (pickup member) of head 40. Fiducial mark M (refer to FIG. 2) is formed at a predetermined position on the upper surface of guide 23b that guides tape 23 in the feeding direction.

Board conveyance device 24 conveys in, fixes, and conveys out board S in the left-right direction (X-axis direction). Board conveyance device 24 has a pair of conveyor belts that is provided at an interval in the front-rear direction and is stretched in the left-right direction in FIG. 1. Board S is conveyed by the conveyor belt.

Movement device 30 includes X-axis slider 32 and Y-axis slider 36, and moves head 40 on an XY plane along the surface of board S. In addition, although not illustrated, movement device 30 also includes an X-axis position sensor that detects a position of X-axis slider 32 in the X-axis direction, a Y-axis position sensor that detects a position of Y-axis slider 36 in the Y-axis direction, and the like. X-axis slider 32 is supported by pair of upper and lower X-axis guide rails 31 provided on a front surface of Y-axis slider 36 in such a manner as to extend in the left-right direction. X-axis slider 32 can move in the left-right direction (X-axis direction) by driving X-axis motor 33 (refer to FIG. 3). Y-axis slider 36 is supported by pair of left and right Y-axis guide rails 35 provided at an upper stage portion of housing 12 in such a manner as to extend in the front-rear direction. Y-axis slider 36 can move in the front-rear direction (Y-axis direction) by driving Y-axis motor 37 (refer to FIG. 3). Head 40 is attached to X-axis slider 32. Accordingly, head 40 can be moved in the XY-directions by movement device 30.

Head 40 picks up component P supplied from tape feeder 20 by suction nozzle 44 and mounts component P on board S. As illustrated in FIG. 2, head 40 includes head main body 41, nozzle holder 42, suction nozzle 44, R-axis drive device 50, Q-axis drive device 60, first Z-axis drive device 70, and second Z-axis drive device 75. Head 40 is configured as a rotary head in which multiple (for example, eight, twenty, or twenty-eight) suction nozzles 44 are held by head main body 41.

Head main body 41 is a rotation body that can be rotated by R-axis drive device 50. Nozzle holders 42 are provided in head main body 41 in such a manner as to be arranged at predetermined angular intervals in a circumferential direction and are supported in such a manner as to be freely lifted and lowered by head main body 41. Suction nozzle 44 is detachably attached to a distal end portion of nozzle holder 42. Suction nozzle 44 picks up component P by a negative pressure supplied by a pressure supply device (not illustrated) via an internal flow path of nozzle holder 42. In addition, suction nozzle 44 releases the pickup of component P by a positive pressure supplied by the pressure supply device via the internal flow path of nozzle holder 42. Although not illustrated, the pressure supply device includes a negative pressure source, a positive pressure source, and a switching valve that can switch the pressure supplied to a suction port of each suction nozzle 44 between the negative pressure, the positive pressure, and an atmospheric pressure.

R-axis drive device 50 causes multiple nozzle holders 42 (multiple suction nozzles 44) to revolve (pivot) about a central axis of head main body 41 along the circumferential direction. As illustrated in FIG. 2, R-axis drive device 50 includes R-axis motor 51, R-axis 52 that extends in the axial direction from the central axis of head main body 41, transmission gear 53 that transmits the rotation of R-axis motor 51 to R-axis 52, and R-axis position sensor 55 (refer to FIG. 3) that detects a rotational position of R-axis motor 51. R-axis drive device 50 causes head main body 41 to rotate by rotationally driving R-axis 52 by R-axis motor 51 via transmission gear 53. Each nozzle holder 42 revolves (pivots) in the circumferential direction together with suction nozzle 44 by the rotation of head main body 41.

Q-axis drive device 60 rotates (spins) each nozzle holder 42 (each suction nozzle 44) about the central axis thereof. As illustrated in FIG. 2, Q-axis drive device 60 includes Q-axis motor 61, cylindrical member 62, transmission gear 63, Q-axis gear 64, and Q-axis position sensor 65 (refer to FIG. 3) that detects a rotational position of Q-axis motor 61. Cylindrical member 62 is inserted coaxially with and rotatable relative to R-axis 52, and has spur gear 62a formed on the outer peripheral surface. Transmission gear 63 transmits the rotation of Q-axis motor 61 to cylindrical member 62. Each Q-axis gear 64 is provided above each nozzle holder 42 and meshes with spur gear 62a of cylindrical member 62 to be slidable in the Z-axis direction (up-down direction). Q-axis drive device 60 collectively rotates each Q-axis gear 64 meshed with spur gears 62a of cylindrical member 62 by rotationally driving cylindrical member 62 via transmission gear 63 by Q-axis motor 61. Each nozzle holder 42 rotates (spins) about the central axis together with suction nozzle 44 by the rotation of Q-axis gear 64.

First and second Z-axis drive devices 70, 75 are capable of individually lifting and lowering nozzle holder 42 in the Z-axis direction (lifting and lowering direction) at two lifting and lowering positions (predetermined positions) on the revolving (pivoting) trajectory of nozzle holder 42. In the present embodiment, first and second Z-axis drive devices 70, 75 are provided along the arrangement direction (X-axis direction) of tape feeders 20.

As illustrated in FIG. 2, first and second Z-axis drive devices 70, 75 include Z-axis sliders 72, 77, Z-axis motors 71, 76 that lift and lower Z-axis sliders 72, 77, and Z-axis position sensors 74, 79 (refer to FIG. 3) that detect the lifting and lowering positions of Z-axis sliders 72, 77. First and second Z-axis drive devices 70, 75 each drive Z-axis motors 71, 76 to lift and lower Z-axis sliders 72, 77, thereby abutting on nozzle holders 42 located below Z-axis sliders 72, 77 to integrally lift and lower nozzle holders 42 with suction nozzles 44. First and second Z-axis drive devices 70, 75 may use linear motors as Z-axis motors 71, 76 to lift and lower Z-axis sliders 72, 77, or may use a rotation motor and a ball screw mechanism to lift and lower Z-axis sliders 72, 77. As described above, head 40 includes two Z-axis drive devices 70, 75 capable of individually lifting and lowering nozzle holders 42 (suction nozzles 44), and can individually perform the pickup operation of component P by suction nozzles 44. In addition, head 40 can also substantially simultaneously lower two suction nozzles 44 by two Z-axis drive devices 70, 75 to substantially simultaneously pick up two components P.

Mark camera 25 is provided on head 40 or X-axis slider 32 and can be moved in the XY-directions by movement device 30. Mark camera 25 captures an image of the fiducial mark attached to board S, fiducial mark M attached to tape feeder 20, component P supplied to the supply position, and the like from above, and outputs the captured image to control device 90.

Part camera 26 is disposed between board conveyance device 24 and tape feeder 20. When suction nozzle 44 that has picked up component P passes above part camera 26, part camera 26 captures an image of component P from below, and outputs the captured image to control device 90.

As illustrated in FIG. 3, control device 90 is configured as a microprocessor centered on CPU 91 and includes ROM 92 for storing processing programs, HDD 93 as an external storage device for storing various types of data, RAM 94 used as a work area, an input and output interface, and the like. The external storage device is not limited to HDD 93, and may be SSD or the like. Control device 90 outputs control signals to tape feeder 20, board conveyance device 24, movement device 30 (X-axis motor 33, Y-axis motor 37), head 40 (R-axis motor 51, Q-axis motor 61, Z-axis motors 71, 76), mark camera 25, and part camera 26. In addition, control device 90 inputs signals from head 40 (R-axis position sensor 55, Q-axis position sensor 65, Z-axis position sensors 74, 79), tape feeder 20, movement device 30, mark camera 25, and part camera 26.

As illustrated in FIG. 3, management device 100 is configured as a microprocessor centered on CPU 101 and includes ROM 102 for storing processing programs, HDD 103 as an external storage device for storing various types of data, RAM 104 used as a work area, an input and output interface, and the like. The external storage device is not limited to HDD 103, and may be SSD or the like. Input device 105 such as a keyboard and a mouse from which a worker inputs various types of commands and display 106 on which various types of information are displayed are connected to management device 100. HDD 103 stores job information including a production program and other production information. Here, the production program defines which components P are to be mounted on which boards S in which order, and how many boards S mounted in this manner are to be produced in mounting device 10.

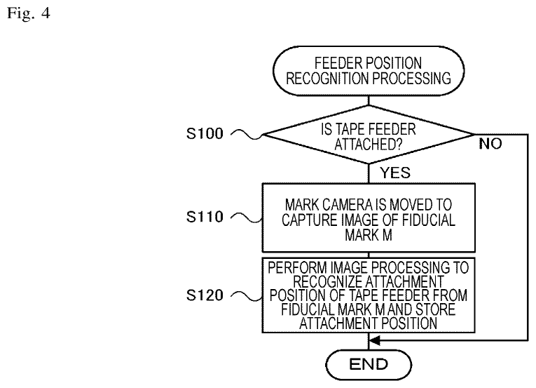

In mounting device 10 configured as described above, processing for recognizing the attachment position of tape feeder 20 is executed. FIG. 4 is a flowchart illustrating an example of feeder position recognition processing. CPU 91 determines whether tape feeder 20 is attached to mounting device 10 (S100), and ends the feeder position recognition processing when it is determined that tape feeder 20 is not attached. On the other hand, when it is determined that tape feeder 20 is attached, CPU 91 causes mark camera 25 to move to a position above tape feeder 20 and to capture an image of fiducial mark M (S110). Next, CPU 91 performs image processing on the captured image to detect fiducial mark M, recognizes the attachment position of tape feeder 20 based on fiducial mark M, stores the attachment position in HDD 103 (S120), and ends the feeder position recognition processing.

Here, tape feeder 20 is detachably set in each slot formed in the feeder table of mounting device 10, and a reference position of tape feeder 20 is determined by a formation pitch of the slot. However, due to a dimensional error or wear of tape feeder 20 or the slot, a slight variation (error) may occur in the actual attachment position with respect to the reference position. By performing the feeder position recognition processing, CPU 91 can recognize the attachment position of tape feeder 20 including such a variation. In the present embodiment, CPU 91 recognizes the attachment position of tape feeder 20 at least in the X-axis direction.

Next, simultaneous pickup processing of component P will be described. FIG. 5 is a flowchart illustrating an example of the simultaneous pickup processing. In the simultaneous pickup processing, CPU 91 detects center FC between the target feeders based on the attachment position of tape feeder 20 (also referred to as a target feeder) that supplies the target component for the simultaneous pickup (S200). In the present embodiment, since the simultaneous pickup is performed by two suction nozzles 44, there are two target feeders. As the attachment position of each target feeder, a position recognized in the feeder position recognition processing and stored in HDD 103 is used. Next, CPU 91 controls movement device 30 such that head 40 is moved to a movement position where center NC of between suction nozzles 44 (also referred to as a target nozzle) that picks up the target component for the simultaneous pickup coincides with center FC between the target feeders (S210).

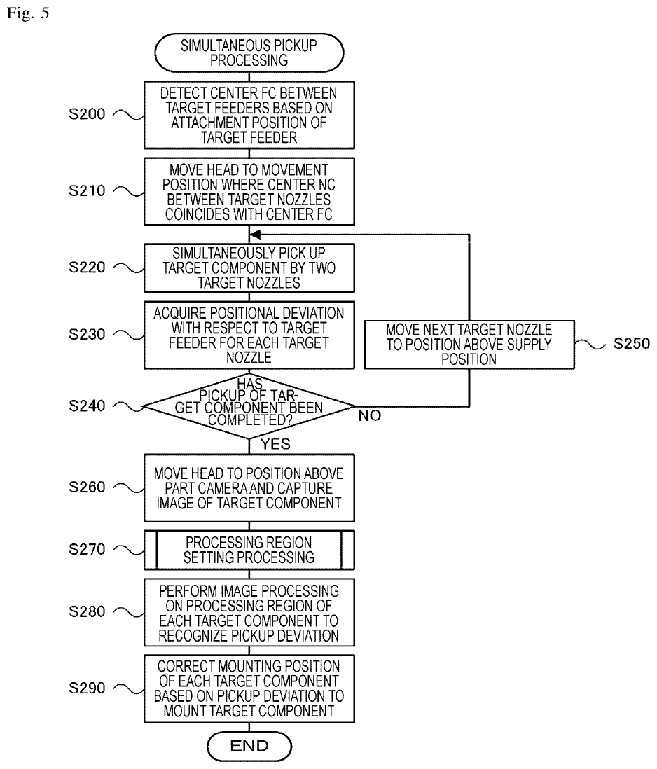

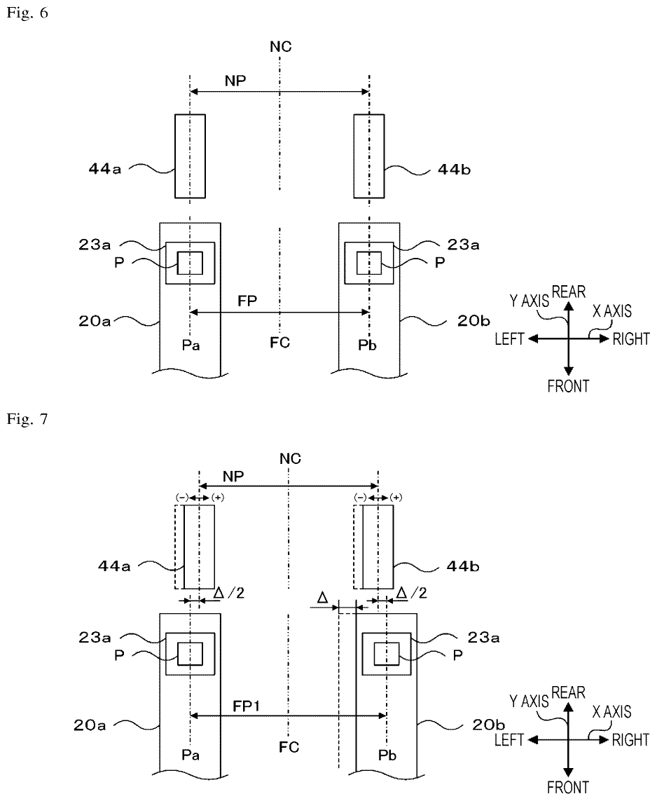

Here, FIGS. 6 and 7 are diagrams illustrating an example of center FC between the target feeders and center NC between the target nozzles. In FIGS. 6 and 7, two target feeders arranged in the left-right direction (X-axis direction) are referred to as target feeders 20a and 20b, and two target nozzles are referred to as target nozzles 44a and 44b. Center FC between the target feeders is the center position of feeder pitch FP in the left-right direction based on attachment position Pa of target feeder 20a and attachment position Pb of target feeder 20b. In addition, center NC between the target nozzles is the center position of nozzle pitch NP in the left-right direction based on the position of target nozzle 44a and the position of target nozzle 44b in head 40. When attachment positions Pa and Pb of target feeders 20a and 20b are the reference positions, feeder pitch FP and nozzle pitch NP coincide with each other. In addition, the position of each suction nozzle 44 in head 40 is obtained in advance by, for example, calibration of head 40 executed before the start of production.

FIG. 6 illustrates a state in which attachment positions Pa and Pb of target feeders 20a and 20b are attached to the reference positions without error. Therefore, even when the position of the target nozzle (head 40) is not adjusted, center FC between the target feeders and center NC between the target nozzles substantially coincide with each other. On the other hand, FIG. 7 illustrates a state in which attachment position Pb of target feeder 20b is deviated to the right side in the drawing by deviation amount Δ with respect to the reference position, and feeder pitch FP1 (>FP in FIG. 6) is formed. Therefore, when the target component is simultaneously picked up while the target nozzle is kept at the position in FIG. 6 (indicated by a dotted line in FIG. 7), the target component picked up by target nozzle 44b may be affected by deviation amount Δ, and pickup failure or mounting failure may occur. Therefore, in the present embodiment, the movement position deviated to the right side in FIG. 7 is determined such that center NC between the target nozzles coincides with center FC between the target feeders, and the target nozzle (head 40) is moved. As a result, since the influence of deviation amount Δ is equally applied to left and right target nozzles 44a and 44b by the deviation amount (Δ/2), it is possible to reduce pickup failure and mounting failure as compared with a case where the influence of deviation amount Δ is applied to only one of left and right target nozzles 44a and 44b. As described above, in S210, head 40 is moved to the movement position where the positional deviation of the target nozzle with respect to the attachment position of the target feeder is not biased to any one of the target nozzles.

Next, CPU 91 causes the two target nozzles to be simultaneously lowered by Z-axis drive device 70, 75 and the two target nozzles to simultaneously pick up the target component (S220). In addition, CPU 91 acquires the positional deviation with respect to the target feeder for each target nozzle that simultaneously picks up the target component, and stores the positional deviation in HDD 103 (S230). FIG. 8 is a diagram illustrating an example of the positional deviation during the simultaneous pickup, and the positional deviation in FIG. 7 is stored. The deviation on the right side with respect to each target nozzle in FIG. 7 is positive, and the deviation on the left side is negative. Therefore, the positional deviation (−Δ/2) is stored in association with target nozzle 44a, and the positional deviation (+Δ/2) is stored in association with target nozzle 44b.

Next, CPU 91 determines whether the pickup of the target component to each target nozzle has been completed (S240). When it is determined that the pickup of the target component has not been completed, CPU 91 causes head main body 41 to rotate by a predetermined amount and the next target nozzle, which does not pick up the target component, to move to a position above the supply position (S250), and executes the processing of S220 to S240. Therefore, every time the simultaneous pickup is performed in each target nozzle, the positional deviation is acquired in association with the target nozzle. On the other hand, when it is determined that the pickup of the target component has been completed, CPU 91 causes head 40 to move to a position above part camera 26 and part camera 26 to capture an image (target component) (S260). Next, CPU 91 executes the processing region setting processing for setting a processing region of image processing of each target component in the captured image (S270).

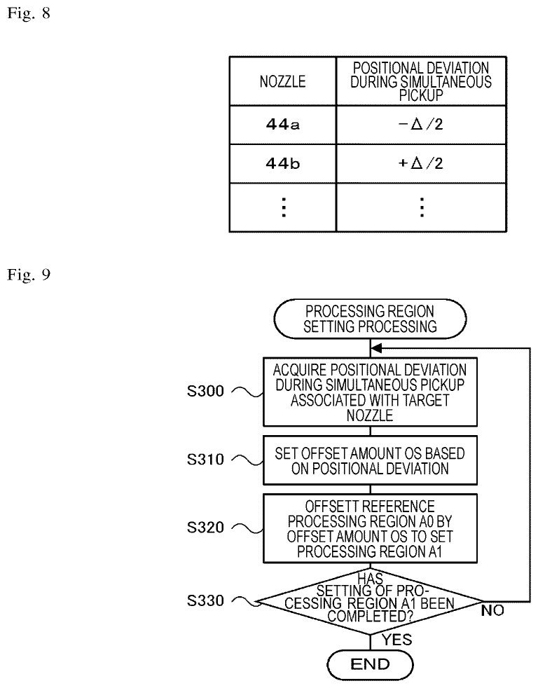

FIG. 9 is a flowchart illustrating an example of processing region setting processing. In the processing region setting processing, CPU 91 acquires the positional deviation during the simultaneous pickup associated with the target nozzle picking up the target component (S300). In S300, the positional deviation (refer to FIG. 8) acquired in S230 and stored in HDD 103 is acquired. Next, CPU 91 sets offset amount OS based on the positional deviation during the simultaneous pickup (S310), and offsets reference processing region A0 associated with the target nozzle by offset amount OS to set processing region A1 of the target component (S320). CPU 91 determines whether the setting of processing region A1 has been completed for all the target components in the image (S330), returns to S300 when it is determined that the setting has not been completed, and ends the processing region setting processing when it is determined that the setting has been completed.

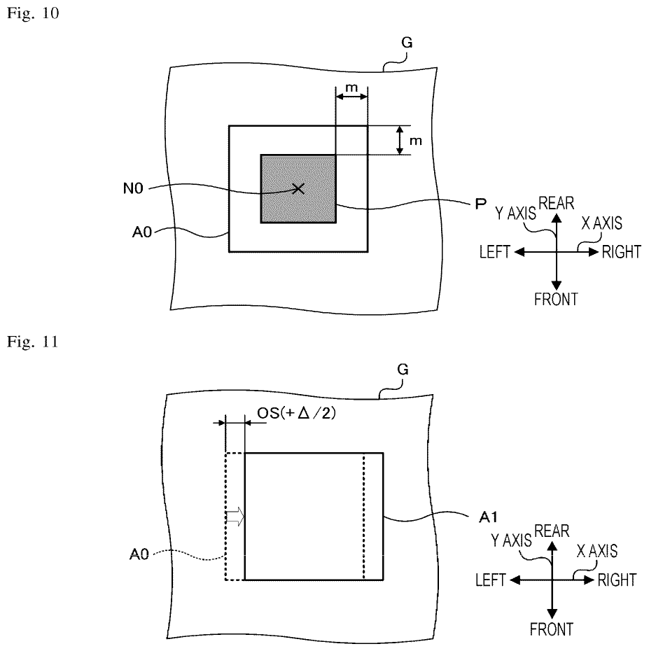

FIG. 10 is a diagram illustrating an example of reference processing region A0. FIG. 11 is a diagram illustrating an example of processing region A1. FIGS. 10 and 11 illustrate a part of image G captured by part camera 26. As illustrated in FIG. 10, reference processing region A0 is set to a size in consideration of the size of component P and deviation amount m due to the positional variation of component P in cavity 23a with center position N0 of suction nozzle 44 in image G as the center. Center position N0 of suction nozzle 44 in image G is determined based on the position of each suction nozzle 44 obtained by the calibration of head 40 described above. The size of reference processing region A0 may be determined based on the size of cavity 23a, regardless of the size of component P.

FIG. 11 illustrates, as an example of processing region A1, processing region A1 for the target component picked up by target nozzle 44b in FIG. 7. As illustrated, processing region A1 (indicated by a solid line in FIG. 11) is set by offsetting reference processing region A0 (indicated by a dotted line in FIG. 11) to the right side by offset amount OS based on the positional deviation (+Δ/2) during the simultaneous pickup. That is, since the supply position of the target component is deviated to the right side with respect to target nozzle 44b (refer to FIG. 7), processing region A1 for the target component picked up by target nozzle 44b is set by offsetting reference processing region A0 to the right side. In addition, although not illustrated, since the supply position of the target component is deviated to the left side with respect to target nozzle 44a (refer to FIG. 7), processing region A1 for the target component picked up by target nozzle 44a is set by offsetting reference processing region A0 to the left side. As described above, processing region A1 is set by offsetting reference processing region A0 according to the positional deviation (deviation amount and deviation direction) during the simultaneous pickup.

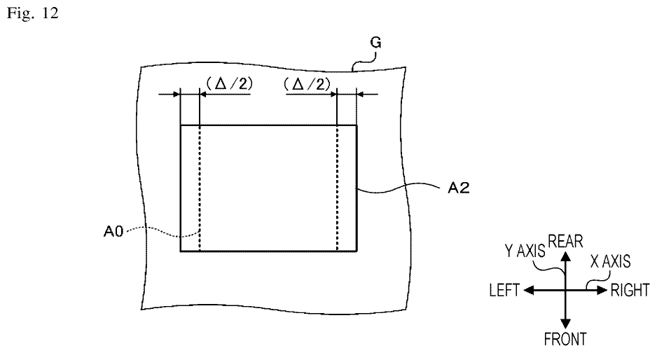

In addition, FIG. 12 is a diagram illustrating an example of processing region A2 of a comparative example. Processing region A2 of the comparative example is set as an enlarged region of reference processing region A0 by adding the positional deviation (Δ/2) during the simultaneous pickup to the left and right of reference processing region A0, for example, as a processing region for each target component picked up by target nozzles 44a and 44b. Therefore, in the comparative example, the processing region for each target component is larger than that in the present embodiment, and as a result, the processing time of the image processing is longer. In particular, since head 40 is a rotary head capable of picking up multiple components and the number of processing regions in image G is relatively large, a delay in processing time becomes a problem. In the present embodiment, since processing region A1 is set by offsetting reference processing region A0 without enlarging reference processing region A0, processing region A1 does not become larger than necessary, and it is possible to prevent the processing time of the image processing from becoming long.

When the processing region setting processing of S270 (FIG. 9) is executed in this manner, CPU 91 performs image processing on processing region A1 of each target component and recognizes the pickup deviation of each target component (S280). In S280, CPU 91 recognizes the pickup deviation of the target component by performing image processing on processing region A1 to recognize the target component and detect the center position of the target component and calculating the positional deviation of each suction nozzle 44 from center position N0 in image G. Next, CPU 91 corrects the mounting position of each target component based on the pickup deviation, mounts the target component on board S (S290), and ends the simultaneous pickup processing. In S290, CPU 91 causes head 40 to move such that the target component picked up by suction nozzle 44 is positioned above the corrected mounting position and suction nozzle 44 to be lowered to mount the target component on board S. CPU 91 performs the mounting operation of S290 until the target components picked up by multiple suction nozzles 44 are mounted.

Here, a correspondence relationship between the elements of the present embodiment and the elements of the present disclosure will be clarified. Control device 90 that executes S230 of the simultaneous pickup processing of the present embodiment corresponds to an acquisition section of the present disclosure, and control device 90 that executes S270 of the simultaneous pickup processing corresponds to a setting section. Head 40 corresponds to a head, movement device 30 corresponds to a moving section, and control device 90 that executes S210 of the simultaneous pickup processing corresponds to a movement control section. Tape feeder 20 corresponds to a feeder, and mark camera 25 corresponds to an imaging section. In the present embodiment, an example of the processing region setting method of the present disclosure is also clarified by describing the operation of mounting device 10.

In mounting device 10 of the embodiment described above, when the simultaneous pickup is performed, the positional deviation of the target nozzle with respect to the attachment position of the target feeder (the supply position of the target component for the simultaneous pickup) is acquired for each target nozzle. In addition, processing region A1 is set for each target component by offsetting reference processing region A0 (predetermined region) defined in image G for each target nozzle that simultaneously picks up the target component based on the positional deviation for each target nozzle. As a result, since it is possible to prevent processing region A1 of the image processing from becoming larger than necessary when the simultaneous pickup is performed, it is possible to appropriately recognize the pickup deviation of the target component while preventing the processing time of the image processing from becoming longer.

In addition, in mounting device 10, head 40 is moved to a movement position where the positional deviation of the target nozzle with respect to the attachment position of the target feeder is not biased to any target nozzle. The positional deviation of the target nozzle is acquired based on the position of the target nozzle performing simultaneous pickup in head 40 moved to the movement position and the attachment position of the target feeder. Therefore, it is possible to prevent processing region A1 from becoming larger than necessary when the simultaneous pickup is performed such that the positional deviation of each target nozzle with respect to each supply position is not biased to any target nozzle.

In addition, in mounting device 10, head 40 is moved to a position where center FC between the two target feeders and center NC between the two target nozzles in the X-axis direction (predetermined direction) coincide with each other, as the movement position. Therefore, it is possible to prevent processing region A1 from becoming larger than necessary while stabilizing the pickup of the target component by equalizing the positional deviation of each target nozzle.

In addition, in mounting device 10, the image captured by mark camera 25 is subjected to image processing to recognize the attachment position of the target feeder, the movement position of head 40 is determined based on the recognized attachment position, and head 40 is moved. Therefore, it is possible to appropriately reflect the error or the positional deviation of the attachment position of the target feeder in the setting of processing region A1.

In addition, in mounting device 10, every time multiple target nozzles are subsequently moved to the lifting and lowering position and the simultaneous pickup is performed, the positional deviation is acquired in association with the target nozzle, and reference processing region A0 is offset based on the positional deviation acquired in association with the target nozzle to set processing region A1. Therefore, when the simultaneous pickup is performed by head 40 configured as a rotary head, processing region A1 of each target component can be appropriately set.

It is needless to say that the present disclosure is not limited to the embodiment described above in any way, and hence can be implemented in various aspects as long as the aspects fall within the technical scope of the present disclosure.

For example, in the above-described embodiment, the present disclosure is applied to the setting of processing region A1 in one image; however, the configuration is not limited to this. For example, in a case where super-resolution processing for generating an image with higher image quality is executed using multiple images captured by part camera 26, the present disclosure may be applied to setting of processing regions in multiple images. In the super-resolution processing, since it is necessary to perform image processing on processing regions of multiple images, the effect of shortening the processing time is increased by setting the processing regions to be offset without enlarging the processing regions. Therefore, it is highly significant to apply the present disclosure.

In the above-described embodiment, head 40 is a rotary head; however, the configuration is not limited to this, and any configuration may be used as long as the simultaneous pickup can be performed by multiple suction nozzles 44. For example, a parallel type head having multiple suction nozzles 44 arranged along the X-axis direction and capable of being independently lifted and lowered may be used. In addition, the configuration is not limited to a configuration in which two suction nozzles 44 perform the simultaneous pickup, and three or more suction nozzles 44 may perform the simultaneous pickup.

In the above-described embodiment, CPU 91 recognizes the attachment position of tape feeder 20 based on the image; however, the configuration is not limited to this, and the attachment position of tape feeder 20 may be recognized using a sensor for position detection or the like. In addition, although CPU 91 recognizes the attachment position of tape feeder 20 as the supply position of the target component, the supply position of the target component may be directly recognized by recognizing component P from the image obtained by capturing an image of component P in cavity 23a with mark camera 25. When the supply position of the target component is deviated in the Y direction, processing region A1 may be set by offsetting the positional deviation in the Y direction similarly to the X direction.

In the above-described embodiment, head 40 is moved to the movement position where center FC between the target feeders and center NC between the target nozzles coincide with each other, so that the positional deviation during the simultaneous pickup is equalized between the two target nozzles; however, the configuration is not limited to this. That is, the positional deviation during the simultaneous pickup need not be biased to one target nozzle, and the positional deviation during the simultaneous pickup may be different between two target nozzles. Alternatively, the positional deviation during the simultaneous pickup may remain biased to one target nozzle, for example, when the positional deviation occurs only in one target nozzle. For example, when the positional deviation is equal to or less than a predetermined amount, the simultaneous pickup may be performed without adjusting the movement position of the target nozzle (head 40) while remaining biased to one target nozzle. Even in such a case, by applying the present disclosure, it is possible to prevent processing region A1 from becoming larger than necessary when the simultaneous pickup is performed.

In the above-described embodiment, the operation of mounting device 10 is described, but an aspect of a processing region setting method of setting processing region A1 of the image processing or an aspect of an image processing method of setting processing region A1 and performing the image processing may be used. In addition, an acquisition section that acquires the positional deviation of each suction nozzle 44 and a setting section that sets the processing region may be provided in different devices.

### Industrial Applicability

The present disclosure can be used in the technical field of mounting processing, the technical field of image processing, and the like.

### REFERENCE SIGNS LIST

10: Mounting device, 12: Housing, 20: Tape feeder, 21: Feeder section, 22: Reel, 23: Tape, 23a: Cavity, 23b: Guide, 24: Board conveyance device, 25: Mark camera, 26: Part camera, 30: Movement device, 31: X-axis guide rail, 32: X-axis slider, 33: X-axis motor, 35: Y-axis guide rail, 36: Y-axis slider, 37: Y-axis motor, 40: Head, 41: Head main body, 42: Nozzle holder, 44: Suction nozzle, 50: R-axis drive device, 51: R-axis motor, 52: R-axis, 53: Transmission gear, 55: R-axis position sensor, 60: Q-axis drive device, 61: Q-axis motor, 62: Cylindrical member, 62a: Spur gear, 63: Transmission gear, 64: Q-axis gear, 65: Q-axis position sensor, 70: First Z-axis drive device, 71, 76: Z-axis motor, 72, 77: Z-axis slider, 74, 79: Z-axis position sensor, 75: Second Z-axis drive device, 90: Control device, 91, 101: CPU, 92, 102: ROM, 93, 103: HDD, 94, 104: RAM, 100: Management device, 105: Input device, 106: Display, A0: Reference processing region, A1, A2: Processing region, M: Fiducial mark, P: Component, S: Board.

1. A mounting device configured to pick up a component supplied to a supply position by a pickup member, perform image processing on an image captured after the pickup to recognize a pickup deviation of the component, and correct the pickup deviation to mount the component, the mounting device comprising:
an acquisition section configured to, when simultaneous pickup of multiple components is performed by multiple pickup members, acquire a positional deviation of each pickup member with respect to each supply position of each target component for the simultaneous pickup for each of the pickup members; and
a setting section configured to set a processing region of the image processing for each target component by offsetting a predetermined region defined in the image for each of the pickup members that have simultaneously picked up the target components, based on the positional deviation of each pickup member acquired by the acquisition section.

2. The mounting device according to claim 1, further comprising:
a head configured to simultaneously lift and lower the multiple pickup members;
a moving section configured to move the head along a plane perpendicular to a lifting and lowering direction of the pickup members; and
a movement control section configured to move the head by the moving section to a movement position where the positional deviation of each pickup member with respect to each supply position is not biased to any one of the pickup members when the simultaneous pickup is performed, wherein
the acquisition section acquires the positional deviation of the pickup member based on a position of each pickup member that performs the simultaneous pickup in the head moved to the movement position, and each supply position of the target component.

3. The mounting device according to claim 2, further comprising:
multiple feeders disposed side by side in a predetermined direction to supply the component to the supply position, wherein
the simultaneous pickup is performed by two pickup members respectively picking up two target components supplied from two feeders, and
the movement control section moves the head to a position where a center between the two feeders in the predetermined direction coincides with a center between the two pickup members, as the movement position.

4. The mounting device according to claim 2, further comprising:
multiple feeders detachably disposed to supply the component to the supply position; and
an imaging section configured to capture an image from which attachment positions of the multiple feeders are detectable, wherein
the movement control section performs image processing on the image captured by the imaging section to recognize the attachment positions of the multiple feeders, and determines the movement position based on the recognized attachment positions to move the head.

5. The mounting device according to claim 1, further comprising:
a head configured to move the multiple pickup members in a circumferential direction and simultaneously lift and lower the pickup members at two or more predetermined positions and configured to subsequently move the multiple pickup members to the predetermined positions to perform the simultaneous pickup, wherein
the acquisition section acquires the positional deviation in association with each pickup member each time the multiple pickup members are subsequently moved to the predetermined positions and the simultaneous pickup is performed, and
the setting section offsets and sets the processing region for each of multiple target components based on the positional deviation acquired in association with the pickup member that has picked up the target component.

6. A processing region setting method when a component supplied to a supply position is picked up by a pickup member and image processing is performed on an image captured after the pickup to recognize a pickup deviation of the component, the processing region setting method comprising:
(a) a step of, when simultaneous pickup of multiple components is performed by multiple pickup members, acquiring a positional deviation of each pickup member with respect to each supply position of each target component for the simultaneous pickup for each of the pickup members; and
(b) a step of setting a processing region of the image processing for each target component by offsetting a predetermined region defined in the image for each of the pickup members that have simultaneously picked up the target components, based on the positional deviation of each pickup member acquired in step (a).
